(19) United States
(12) Patent Application Publication
(10) Pub. No.: US 2015/0303091 A1
(43) Pub. Date: Oct. 22, 2015

(54) DEVICE FOR ORIENTING A WAFER ON A WAFER CARRIER

(71) Applicant: AIXTRON SE, Herzogenrath (DE)

(72) Inventors: Francisco RUDA Y WITT, Eschweiler (DE); Marcel KOLLBERG, Würselen (DE); Roland PÜSCHE, Aachen (DE); Torsten BASTKE, Würselen (DE)

(21) Appl. No.: 14/646,090

(22) PCT Filed: Nov. 4, 2013
(86) PCT No.: PCT/EP2013/072889

§ 371 Date: May 20, 2015

(30) Foreign Application Priority Data
Nov. 20, 2012 (DE) 10 2012 111 167.7

(51) Int. Cl. H01L 21/68

(52) U.S. Cl. CPC H01L 21/68

(57) ABSTRACT

The aim of the invention is to improve the automated loading of a susceptor with wafers. According to the invention a device for orienting a wafer on a wafer carrier (11) comprises a base element (2) on which to set the wafer carrier (11), wherein the base element (2) has a centering section (3), which interacts with a counter centering section (10) of the wafer carrier (11) in such a way that the wafer carrier (11) set onto the base element (2) assumes a predetermined position in relation to the base element (2), and comprising a centering element (1), which is arranged above the base element (2) and has a predetermined position in relation to the base element (2) and has an adjusting-element carrier (5), on which adjusting elements (6) are arranged in an arrangement corresponding to an outer contour of the wafer, in order to orient the wafer in a plane parallel to the supporting surface (11′) of the wafer carrier.

DE 102 32 731 A1 and DE 10 2010 017 082 describe a loading plate, which forms a wafer carrier, and which forms a support surface lying in the horizontal, on which a disk made of a semiconductor material, which is referred to hereafter as a wafer, can be placed. Using the wafer carrier, the wafer is moved into a processing chamber of a coating facility, where one or more layers are deposited on the wafer. This is performed using automatic handling machines, as are described, for example, as described in U.S. Pat. No. 5,162,047, U.S. Pat. No. 5,334,257, U.S. Pat. No. 5,626,456, or U.S. Ser. No. 6,318,957. To achieve optimum, i.e., uniform coating, it is advantageous if gaps, which cannot be prevented, in particular along the edges of the wafer inserted into a pocket of the susceptor, are kept as small as possible. Furthermore, the need exists for equipping a susceptor with a plurality of wafer carriers, which each support wafers.

The invention is therefore based on the object of improving the automatic loading of a susceptor with wafers.

The object is achieved by the invention specified in the claims.

The device according to the invention has a base element for placement of the wafer carrier, wherein the base element has a centering section, which cooperates with a counter centering section of the wafer carrier such that the wafer carrier assumes a predetermined location in relation to the base element. The base element can be, for example, a base plate. The centering section is located on this base plate. In a simplest form, the centering section can be formed by a centering pedestal, for example, having diagonally extending walls. The centering section is preferably implemented by a truncated-cone-shaped projection, which extends vertically upward out of the base plate. However, it is also possible to design the centering section differently. The counter centering section, which is associated with the lower side of the wafer carrier, can have a negative shape (cavity) corresponding to the centering section. The object of the centering section in cooperation with the counter centering section is reproducible location positioning of the wafer carrier on the base element. Furthermore, a centering element arranged above the base element is provided. It can be fixedly connected to the base element. However, it is also provided that the centering element is seated detachably on the base element. In any case, however, the centering element fastened on the base element has a predetermined location relationship to the base element. The centering element has an adjustment element carrier. The adjustment element carrier can be designed in the manner of an open-gap ring. The ring can be open toward its edge. For example, it can form the shape of a horseshoe, a U, or a C in a top view. It can enclose an opening (passage clearance), the diameter of which is larger than the diameter of the wafer. Since the wafer typically has a circular disk design, the opening of the adjustment element carrier preferably has an edge extending on a circular arc line. The adjustment element carrier carries adjustment elements. These are arranged in an arrangement corresponding to the outline contour of the wafer. The adjustment elements are designed so that they can orient the wafer in a plane parallel to the support surface of the wafer. The orientation of the wafer is performed vertically above the wafer carrier. In a preferred embodiment of the invention, the adjustment elements have diagonal flanks The diagonal flanks face toward the opening in this case. The diagonal flanks form sliding surfaces, along which the edge of a wafer lower through the opening of the centering element can slide. In this case, the wafer is displaced in a direction transverse to the lowering movement into a predetermined centering position. The opening is only enclosed over a partial circumferential length by the adjustment element carrier. An engagement region for the handling arm remains. In such an embodiment, the wafer lies on a handling arm suitable for wafer transport. Edge sections of the wafer protrude beyond the handling arm in this case. These edge sections of the wafer can slide along the diagonal flanks of the adjustment elements during the lowering movement, wherein the wafer can then shift in the horizontal direction on the handling arm. The movement of the handling arm is a solely vertical downward displacement in this case. The adjustment elements can be fastened so they are detachable and are displaceable transversely to the edge of the opening on the adjustment element carrier. As a result of this embodiment, the adjustment elements may be calibrated in a predetermined position. Support pins can protrude vertically upward from the base element in the direction toward the opening. The height of the support pins is greater than the vertical height of the wafer carrier, so that the support pins can protrude through the ring clearance or through separate boreholes of the ring-shaped wafer carrier. The ends of the support pins protrude beyond the support surface of the wafer carrier in this case. On the other hand, the spacing between the free ends of the support pins and the lower side of the adjustment element carrier is sufficiently large to be able to move the wafer carrier through this clearance. Using a handling arm assigned to the wafer carrier, the wafer carrier can therefore be moved through the intermediate space between the support pins and the lower side of the adjustment element carrier and placed on the base element, wherein the support pins protrude either through individual boreholes or through a ring clearance of the wafer carrier. The handling arm preferably has a fork shape for the transport of the wafer carrier. The two fork tines can engage below a ring-shaped collar of the wafer carrier. If the wafer is moved with the wafer carrier assigned thereto through the orientation opening of the adjustment element, the wafer is thus oriented in the horizontal direction. In the course of the further lowering movement of the handling arm, the wafer is laid on the ends of the support pins. The wafer carrier is subsequently lifted with the handling arm associated with the wafer carrier. The lifting of the wafer carrier is performed exactly in the vertical direction, so that the wafer carrier receives the wafer in a predetermined position, which is defined by the location of the adjustment elements. In this case, the wafer lies in a depression of the support surface, the edge of which only has a minimum spacing to the edge of the wafer. A calibration tool is provided to calibrate the location of the adjustment elements. The calibration tool has a counter centering section, with which it can be placed on the centering section of the base element. At the height of the adjustment elements, the calibration tool has a calibration section. It can be formed by a step, for example, by a cylinder jacket wall, which extends on the outline contour of a wafer. This calibration section lies at the height of the adjustment elements, so that the adjustment elements can be brought into contact against the calibration section. The adjustment elements are fastened so that they are displaceable on the adjustment element carrier transversely to a tangential to the edge of the calibration section. For this purpose, the adjustment element carrier can have grooves or ribs, which are oriented radially in relation to the center of the wafer or the opening of the adjustment element carrier, and which are used for guiding the adjustment elements. Location fixing of an adjustment element can be performed with the aid of a clamping screw.

Exemplary embodiments of the invention are explained hereafter on the basis of appended drawings. In the figures:

FIG. 1 shows a perspective illustration of a first exemplary embodiment of an orientation device,

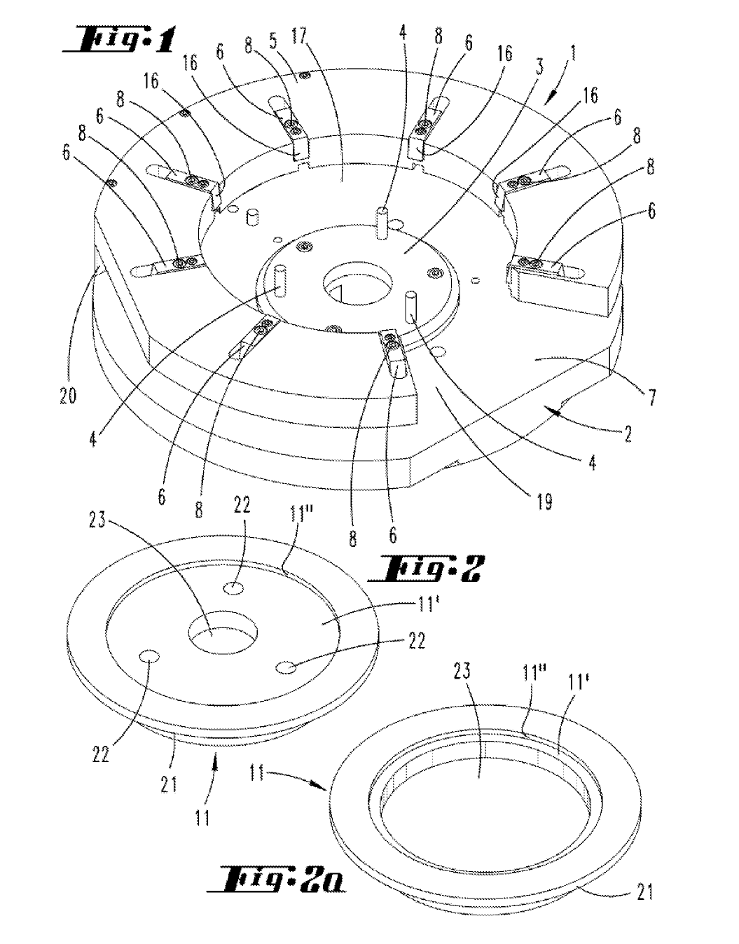

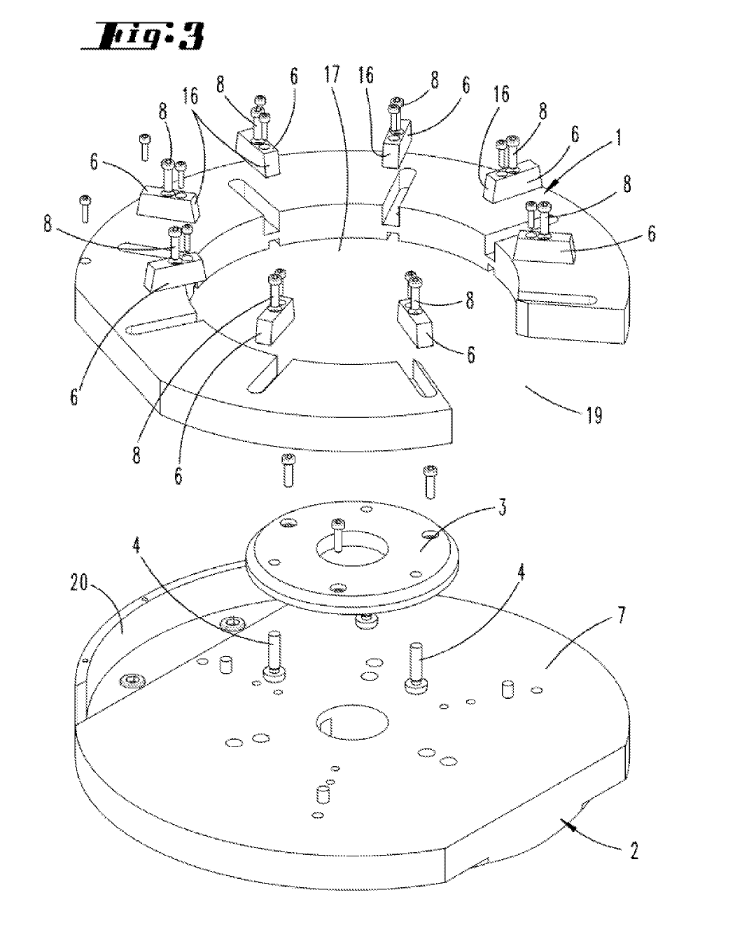

FIG. 2 shows a perspective illustration of a wafer carrier,

FIG. 2a shows a perspective illustration of a wafer carrier designed as a transfer ring;

FIG. 3 shows an exploded illustration of the orientation device having wafer carrier,

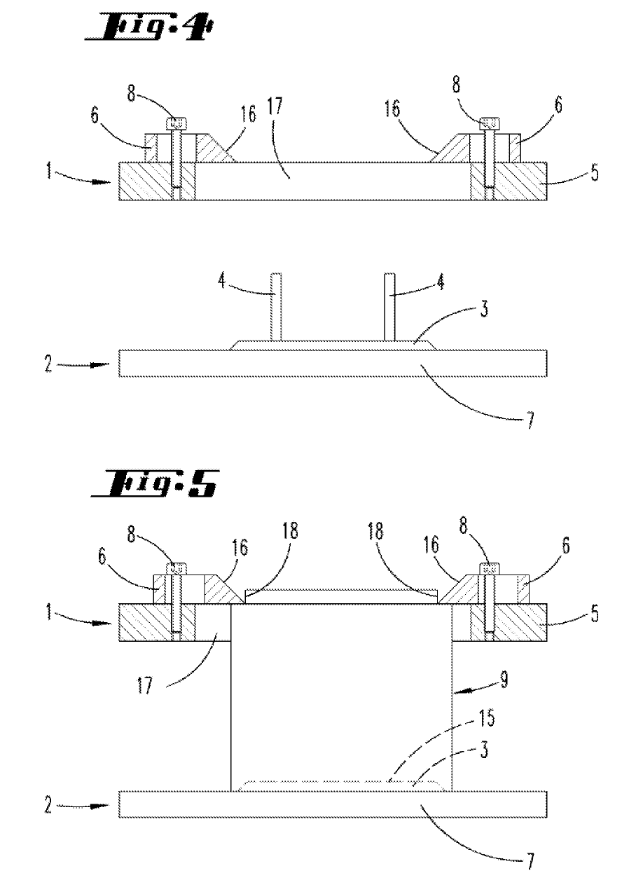

FIG. 4 shows a schematic illustration of the device as a side view of an orientation device,

FIG. 5 shows an illustration according to FIG. 4 having calibration tool 9 inserted in the orientation device,

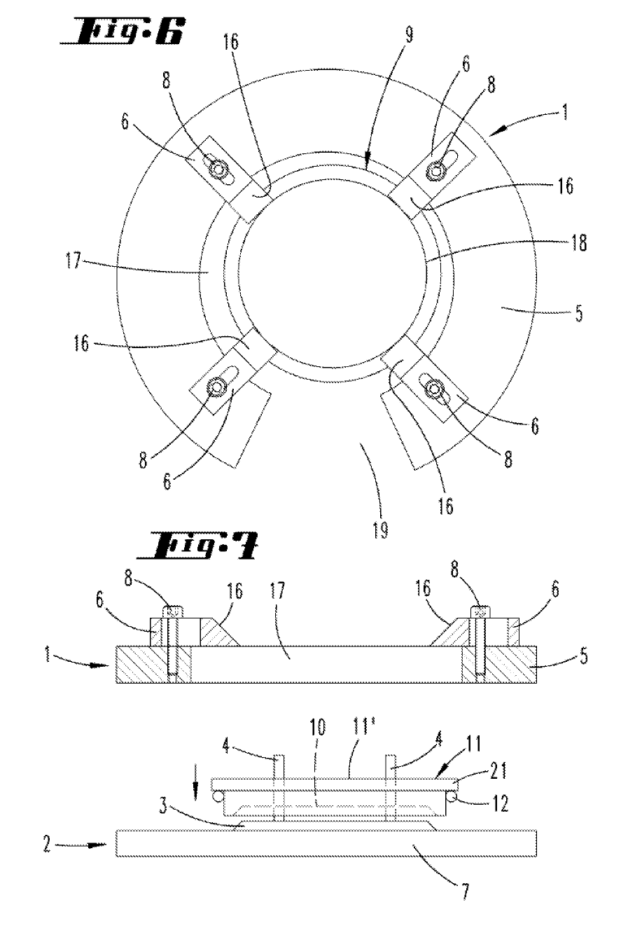

FIG. 6 shows a top view according to arrow VI in FIG. 5,

FIG. 7 shows an illustration according to FIG. 4 having a wafer carrier 11, which is placed by a handling arm 12 on the base element 2,

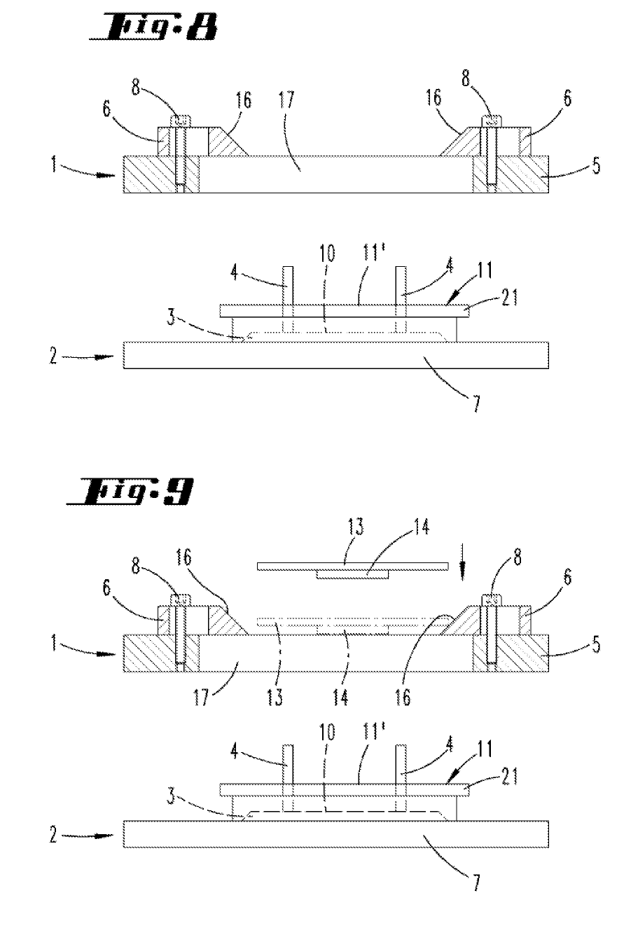

FIG. 8 shows a sequential illustration to FIG. 7, wherein the wafer carrier 11 has been placed on the base element 2,

FIG. 9 shows a sequential illustration to FIG. 3, wherein a handling arm 14 lowers a wafer 13, which meets with an edge section against a diagonal flank 16 of an adjustment element 6 in the dot-dash illustration;

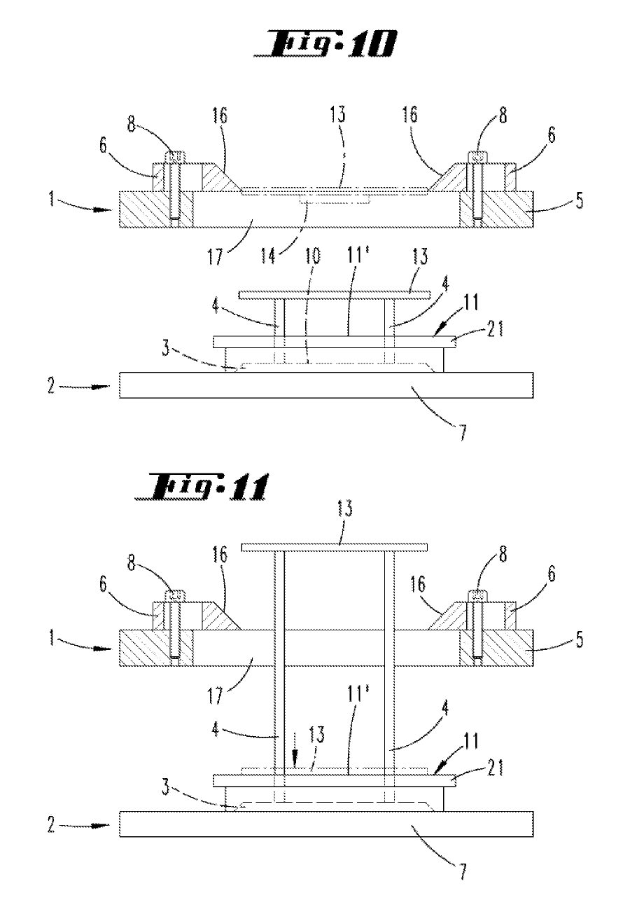

FIG. 10 shows a further sequential illustration, in which the wafer 11 rests on the support pins 4 above the wafer carrier 11, after it has been adjusted by the adjustment elements 6 (in the dot-dash illustration);

FIG. 11 shows a sectional illustration similar to FIG. 10 of a second exemplary embodiment;

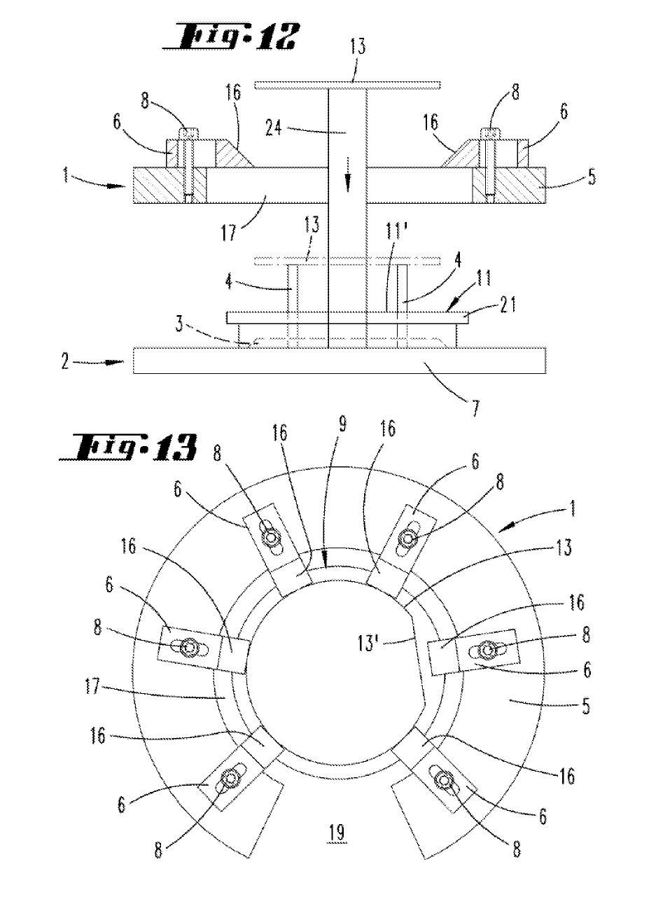

FIG. 12 shows a sectional illustration similar to FIG. 10 of a third exemplary embodiment, and

FIG. 13 shows a top view of the centering element 1 having wafer 13 located between the adjustment elements 6.

The orientation device illustrated in the drawings has a base element 2 having a base plate 7. The base plate 7 essentially has the form of a circular disk. A support wall 20, which carries a centering element 1, protrudes from an edge region of the base plate 7. The centering element 1 has an essentially ring-shaped adjustment element carrier 5.

A centering section 3 in the form of a truncated-cone-shaped pedestal is located in the center of the bottom surface of the base plate 7. The truncated-cone-shaped pedestal 3 is screwed together with the base plate. A total of three support pins protrude in the vertical direction from the base plate 7 through the truncated-cone-shaped pedestal 3.

The adjustment element carrier 5 only encloses a partial region of an opening 17. The adjustment element carrier 5 has an engagement region 19, so that in the top view it approximately has the shape of a C, a horseshoe, or a U. A handling arm 14 for handling a wafer 13 can travel in the vertical direction through the engagement region 19.

Multiple adjustment elements 6 are arranged on the upper side of the adjustment element carrier 5 with essentially equal circumferential distribution around the center of the opening 17, which is circular in the exemplary embodiment. Each of the adjustment elements 6 is arranged in this case in a groove and is displaceable in the radial direction in relation to the center of the opening 17, if a fastening screw 8 is loosened. When the fastening screw 8 is tightened, the adjustment element 6 is fixed in place.

Each of the total of eight adjustment elements 6 therein has a diagonal flank 16 facing toward the center of the opening 17.

FIGS. 2 and 2a each describe a wafer carrier, which essentially has a ring shape. The upwardly-facing upper side of the wafer carrier 11 implements a support surface 11′, on which a wafer 13 is to be laid. The wafer carrier 11 has a cavity on its lower side that forms a counter centering section 10. If the counter centering section 10 is placed on the centering section 3, the wafer carrier 11 thus assumes a defined location in relation to the adjustment element carrier 5 or the adjustment elements 6. In a simplest embodiment (FIG. 2a), the wafer carrier is implemented as a transfer ring. It has a circumferential collar 21, under which the fork tines of a fork-shaped handling arm 12 can engage.

The two wafer carriers 11 shown in FIGS. 2, 2a have a pocket having a circular edge 11″ on their upper side. The bottom of the pocket forms the support surface 11′. The two wafer carriers 11 essentially only differ in the size of the diameter of the ring opening 23. The wafer carrier 11 shown in FIG. 2 has a small diameter of the ring opening 23, so that separate boreholes 22 are provided for the support pins. In the wafer carrier 11 shown in FIG. 2a, the support surface 11′ only extends over a narrow edge region, which adjoins the edge 11″ of the pocket.

FIG. 4 shows a schematic illustration in cross section of the essential elements of an orientation device according to the invention, namely a base element 2 having a base plate 7, which carries a centering section 3 and from which the support pins 4 protrude upward. The centering element 1 is fixedly connected to the base plate 2 using means which are not shown. It has an adjustment element carrier 5, which only carries four adjustment elements 6 in the schematic illustration. Each adjustment element 6 has a diagonal flank 16, wherein the diagonal angles of the diagonal flanks 16 extend so that the diagonal faces downward in the direction toward the opening 17. The adjustment elements 6 have slots, through each of which a fastening screw 8 protrudes, which is screwed into a threaded borehole of the adjustment element carrier 5.

FIGS. 5 and 6 show the use of a calibration tool 9. The calibration tool 9 is, in the exemplary embodiment, an essentially cylindrical body, the lower side of which forms a cavity 15, which forms a counter centering section, which can be placed on the centering section 3, so that the calibration tool 9 assumes a defined position in relation to the adjustment elements 6. The pointed ends of the diagonal flanks 16 are moved against a calibration section 18 of the calibration tool 9 when the screws 8 are loosened. The calibration section 18 is formed by a cylinder jacket wall, which extends on an outline contour, which corresponds to the outline contour of a wafer 13.

The equipping of a wafer carrier 11 with a wafer 13 will be explained on the basis of FIGS. 7 to 10:

Firstly, a wafer carrier 11, which can be a transfer ring, is placed on the base plate 7 by means of a handling arm 12. In this case, the centering section 3 engages in the counter centering section 10 and moves the wafer carrier 11 into a laterally centered position. The wafer carrier 11 is moved in this case by the handling arm 12 under the adjustment element carrier 5 through into a position above the support pins 4 and then lowered according to FIG. 7, so that it assumes the position illustrated in FIG. 8.

A differently designed handling arm 14 engages below an essentially circular wafer 13, which is a semiconductor substrate, and which is to be laid on the wafer carrier 11. It can be a flat circular disk in this case, which consists of silicon, germanium, gallium arsenide, indium phosphite, or another material. The wafer 13 has an undefined position in relation to the handling arm 14. The handling arm 14—as shown in FIG. 9—is displaced vertically downward through the engagement region 19, wherein the wafer 13 passes through the opening 17. Since the wafer 13 has an undefined location on the handling arm 14, sections of the edge of the wafer 13 meet against the diagonal flanks 16 in the course of the downward movement. A horizontal force component develops therefrom, which displaces the wafer 13 in the direction toward the center of the opening 17. This is shown by dot-dash lines in FIG. 9.

FIG. 10 shows, with dot-dash lines, the wafer 13 during the exit from the centering element 1, in which its edge leaves the blade-like tips of the diagonal flanks 16. The wafer 13 is deposited on the ends of the support pins 4 by a further lowering movement of the handling arm 14.

With the handling arm 12 for the wafer carrier, the wafer carrier 12 is then lifted vertically upward, wherein the wafer 13 comes to rest in an oriented position on the support surface 11′ of the wafer carrier 11. The support surface 11′ of the wafer carrier can form a pocket, the circumferential contour of which corresponds to the circumferential contour of the wafer 13 and the depth of which approximately corresponds to the material thickness of the wafer. As a result of the centering orientation function of the device, the wafer is oriented in relation to the pocket in the support surface 11′ of the wafer carrier 11 such that it fits precisely into the pocket. The edge 11″ of the pocket therefore only has to have a minimal excess, so that the gap between pocket wall and wafer edge is minimized.

FIG. 11 shows an illustration according to FIG. 10 of a second exemplary embodiment. In this exemplary embodiment, the support pins 4 are lengthened and are movable in the vertical direction. In this exemplary embodiment, the support pins 4 are components of a lifting device. Drive means (not shown) are provided, to displace the support pins 4 in the vertical direction. The support pins 4 have a length that is greater than the spacing between the centering element 1 and the base element 2. The length of the support pins is sufficiently greater than the spacing that the upwardly facing end faces of the support pins 4 protrude beyond the highest protrusion of the centering element 1, i.e., in particular beyond the adjustment elements 6. By means of the lifting device (not shown), the support pins 4 may be lowered from the loading position shown in FIG. 11, to lay the wafer 13 on the wafer carrier 11.

By means of a handling arm, an uncentered wafer 13 can be laid on the ends of the support pins 4, which are pushed through upward through the opening 17. The support pins 4 are then displaced downward in the direction of the arrow. In this case, edge sections of the uncentered wafer 13 resting on the support pins 4 slide along the diagonal flanks 16, until the wafer 13 has reached its centered position illustrated in FIG. 13.

A further downward displacement of the wafer 13 is then performed, until the wafer rests on the wafer carrier 11. This is shown by dot-dash lines in FIG. 11. The support pins 4 only protrude into the wafer carrier 11 in this end position, but not beyond its support surface 11′.

In the exemplary embodiment illustrated in FIG. 12, a vertically displaceable stamp 24 is located in the center of the base plate 7. A lift drive is provided for this purpose, which is not shown in the drawings. The lift unit is capable of displacing the stamp 24 between two end positions. In the first end position, the upwardly facing end face of the stamp 24 lies above the diagonal flanks 16 of the adjustment elements 6. In a second position, the end face of the stamp 24 lies below the end faces of support pins 4 or below a wafer carrier 11, depending on whether the wafer 13 is to be deposited on the end faces of support pins 4 or directly on the wafer carrier 11. The stamp 24 is arranged in the center of the opening 17, so that it only supports the center of the wafer 13. The edge regions of the wafer 13 lie radially outside the stamp 24.

From the downwardly displaced position, the stamp 24 can be moved up in the vertical direction so that its upper end lies above the centering element 1. A wafer 13 can be laid on the end face of the stamp 24 by means of a handling arm. The wafer 13 is not centered. If the stamp 24 is displaced downward in the direction of the arrow, the edges of the uncentered wafer 13 thus slide along the diagonal flanks 16, wherein the wafer is moved into the centered position illustrated in FIG. 13. Further lowering of the stamp 24 has the result that the wafer 13 is laid on the ends of the support pins 4, as illustrated in FIG. 12.

FIG. 13 shows that as a result of the arrangement of the adjustment elements 6, the orientation of a flattening 13′ of a wafer 13 is unimportant. The adjustment elements 6 are arranged so that the flattening 13′ can also lie in front of one or two adjustment elements 6. The adjustment elements 6 are arranged in the circumferential direction in a plurality such that at least three adjustment elements 6 unfold a centering action and cooperate for this purpose with the edge section of the wafer 13 extending on a circular arc line.

All disclosed features are essential to the invention (per se). The content of the disclosure of the associated/appended priority documents (copy of the previous application) is also hereby incorporated in its entirety in the disclosure of the application, also for the purpose of incorporating features of these documents in claims of the present application. The dependent claims characterize, in their optional secondary version, independent refinements according to the invention of the prior art, in particular to be able to perform divisional applications on the basis of these claims.

### LIST OF REFERENCE NUMERALS

1 centering element

2 base element

3 centering section

4 support pin

5 adjustment element carrier

6 adjustment element

7 base plate

8 screw

9 calibration tool

10 counter centering section

11 wafer carrier

11′ support surface

11″ edge

12 handling arm for ring

13 wafer

13′ flattening

14 handling arm for wafer

15 counter centering section

16 diagonal flank

17 opening

18 calibration section

19 engagement region

20 support wall

21 collar

22 opening for support pin

23 ring opening

24 stamp

1. A device for orienting a wafer on a wafer carrier (11), comprising a base element (2) for placing the wafer carrier (11), wherein the base element (2) has a centering section (3), which cooperates with a counter centering section (10) of the wafer carrier (11) such that the wafer carrier (11) placed on the base element (2) assumes a predetermined location in relation to the base element (2), having a centering element (1), which is arranged above the base element (2), and which has a predetermined location relationship to the base element (2), and has an adjustment element carrier (5), on which adjustment elements (6) are arranged in an arrangement corresponding to an outline contour of a wafer (13), to orient the wafer (13) in a plane parallel to a support surface (11′) of the wafer carrier.

2. The device according to claim 1, characterized in that the adjustment elements (6) have diagonal flanks (16), on which edge sections of the wafer (13), which is lowered by a handling arm (14) through an opening (17) of the centering element (1), can slide.

3. The device according to claim 2, characterized in that the opening (17) is only enclosed over a partial circumferential length by the adjustment element carrier (5) and forms an engagement region (19) for the handling arm (14).

4. The device according to claim 2, characterized in that the adjustment elements (6) are fastened on the adjustment element carrier (5) so they can be loosened and are displaceable in the loosened state transversely to the edge of the opening (17).

5. The device according to claim 2, characterized in that the centering section (3) is a pedestal, in the shape of a truncated cone.

6. The device according to claim 2, characterized in that the wafer carrier (11) has a ring shape.

7. The device according to claim 2, characterized in that the wafer carrier (11) has a collar (21) for a handling arm (12) to engage below.

8. The device according to claim 2, characterized by support pins (4), which protrude from the base element (2) in the direction toward the opening (17), for placement of the wafer (13).

9. The device according to claim 1, characterized by a calibration tool (9), having a counter centering section (15) which can be placed on the centering section (3) of the base element (2), and having a calibration section (18), against which the location of adjustment elements (6), which are fastened adjustably on the adjustment element carrier (5), can be moved.

10. The device according to claim 9, characterized in that the calibration section (18) of the calibration tool (9) is a step, which extends along an outline contour of the wafer (13).

11. The device according to claim 9, characterized by lifting element (4, 24), on which the wafer (13) can be laid, which can be lowered, so that the wafer (13) resting on the lifting element (4, 24) is centered during passage through the centering element (1), whereby the lifting element (24) deposits the wafer (13) on the wafer carrier (11).
